(19) United States
(12) Patent Application Publication
(10) Pub. No.: US 2025/0140726 A1
(43) Pub. Date: May 1, 2025

(54) SEMICONDUCTOR PACKAGE

(71) Applicant: SAMSUNG ELECTRONICS CO., LTD., SUWON-SI (KR)

(72) Inventors: Kyunglyul LEE, Suwon-si (KR); Jooyoung OH, Suwon-si (KR)

(21) Appl. No.: 18/738,153

(22) Filed: Jun. 10, 2024

(30) Foreign Application Priority Data
Oct. 31, 2023 (KR) 10-2023-0147405

(51) Int. Cl. H01L 23/00

(52) U.S. Cl. CPC H01L 24/14; H01L 24/05; H01L 24/06; H01L 24/08; H01L 24/16; H01L 2224/05017; H01L 2224/05147; H01L 2224/0603; H01L 2224/06051; H01L 2224/08225; H01L 2224/1403; H01L 2224/16227; H01L 2924/3511

(57) ABSTRACT

A semiconductor package includes: a package substrate having a first region and a second region; first connection pads disposed on the first region of the package substrate, and having a first height; second connection pads disposed on the second region of the package substrate, and having a second height that is lower than the first height; a semiconductor chip including first chip pads, second chip pads, and a protective insulating layer, wherein the first chip pads are disposed in the first region, wherein the second chip pads are disposed in the second region, and wherein the protective insulating layer is disposed on the second chip pads; first bump structures disposed on the first chip pads, and respectively connected to the first connection pads; and second bump structures disposed on the protective insulating layer, wherein the second bump structures are respectively connected to the second connection pads.

### CROSS-REFERENCE TO RELATED APPLICATION

This application claims priority under 35 U.S.C. 119 to Korean Patent Application No. 10-2023-0147405 filed on Oct. 31, 2023 in the Korean Intellectual Property Office, the disclosure of which is incorporated by reference herein in its entirety.

### TECHNICAL FIELD

Example embodiments of the present inventive concept relate to a semiconductor package.

### DISCUSSION OF THE RELATED ART

As electronic devices have become smaller with reduced weight and increased performance, semiconductor packages have been under development to have a reduced size and increased performance. As a plurality of materials are mounted in a single package, a difference in thermal expansion coefficients may occur, and a resulting warpage phenomenon may occur.

### SUMMARY

According to an example embodiment of the present inventive concept, a semiconductor package includes: a package substrate having a first region and a second region that is adjacent to the first region; first connection pads disposed on the first region of the package substrate, wherein each of the first connection pads has a first height; second connection pads disposed on the second region of the package substrate, wherein each of the second connection pads has a second height that is lower than the first height; a semiconductor chip including first chip pads, second chip pads, and a protective insulating layer, wherein the first chip pads are disposed in the first region, wherein the second chip pads are disposed in the second region, and wherein the protective insulating layer is disposed on the second chip pads; first bump structures disposed on the first chip pads, wherein the first bump structures are respectively connected to the first connection pads; and second bump structures disposed on the protective insulating layer, wherein the second bump structures are respectively connected to the second connection pads.

According to an example embodiment of the present inventive concept, a semiconductor package includes: a package substrate; first and second connection pads disposed on the package substrate and spaced apart from each other; bump structures in contact with at least one of the first or second connection pads; and a semiconductor chip disposed on the bump structures, wherein the semiconductor chip includes a protective insulating layer disposed on bump structures, which overlap the second connection pads, among the bump structures, wherein upper surfaces of the first connection pads are positioned on a level higher than that of upper surfaces of the second connection pads.

According to an example embodiment of the present inventive concept, a method of manufacturing a semiconductor package includes: forming preliminary connection pads on a preliminary package substrate, forming a preliminary protective layer covering the preliminary connection pads, wherein the preliminary connection pads include first and second preliminary connection pads that are spaced apart from each other; exposing the preliminary connection pads by removing a portion of the preliminary protective layer, wherein a remainder of the preliminary protective layer forms a protective layer, and wherein a package substrate including the protective layer is formed; forming second connection pads by removing a portion of the second preliminary connection pads; forming bump structures connected to first connection pads and the second connection pads; disposing insulating structures on bump structures, which overlap the second connection pads in a vertical direction, among the bump structures; mounting a semiconductor chip on the bump structures and the insulating structures; and forming an encapsulant covering the semiconductor chip, on the package substrate.

### BRIEF DESCRIPTION OF DRAWINGS

The above and other aspects of the present inventive concept will become more apparent by describing in detail example embodiments thereof, with reference to the accompanying drawings, in which:

FIG. 1A is a cross-sectional view illustrating a semiconductor package according to an example embodiment of the present inventive concept, and FIG. 1B is a partially enlarged view illustrating region “A” of FIG. 1A;

FIG. 2A is a cross-sectional view illustrating a semiconductor package according to an example embodiment of the present inventive concept, and FIG. 2B is a partially enlarged view illustrating region “A” of FIG. 2A;

FIG. 3A is a cross-sectional view illustrating a semiconductor package according to an example embodiment of the present inventive concept, and FIG. 3B is a partially enlarged view illustrating region “A” of FIG. 3A; and

FIGS. 4, 5A, 5B, 6, and 7 are schematic cross-sectional views illustrating a process of manufacturing a semiconductor package according to an example embodiment of the present inventive concept.

### DETAILED DESCRIPTION OF THE EMBODIMENTS

Hereinafter, example embodiments of the present inventive concept will be described in detail.

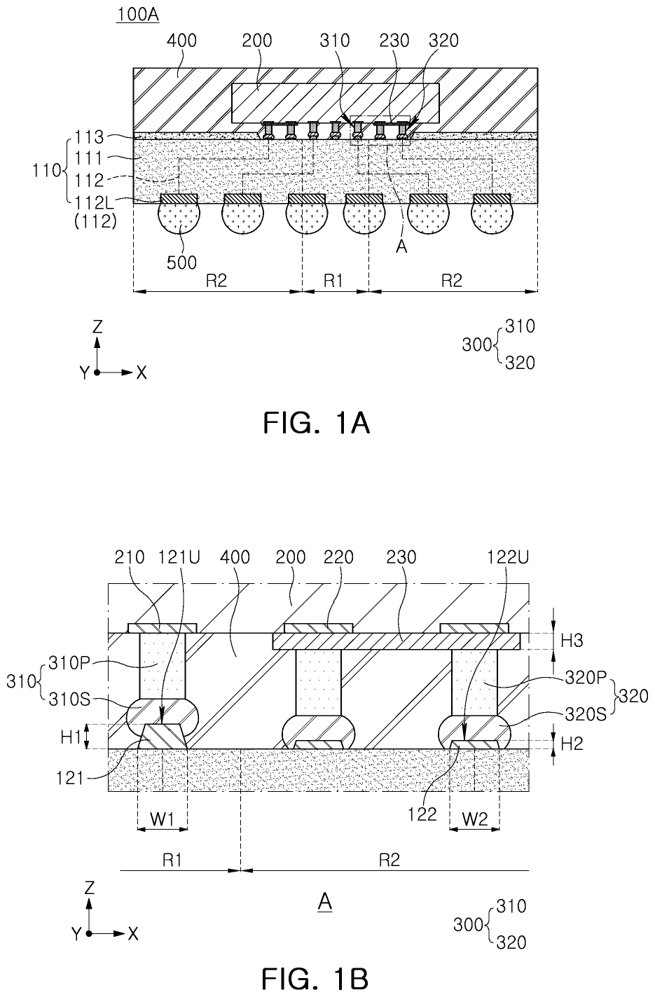

FIG. 1A is a cross-sectional view illustrating a semiconductor package according to an example embodiment of the present inventive concept, and FIG. 1B is a partially enlarged view illustrating region “A” of FIG. 1A.

Referring to FIGS. 1A and 1B, a semiconductor package 100A according to an example embodiment of the present inventive concept may include a package substrate 110, first connection pads 121, second connection pads 122, a semiconductor chip 200, and bump structures 300. Referring to FIGS. 1A and 1B, the semiconductor package 100A according to an example embodiment of the present inventive concept may further include an encapsulant 400 and external connection conductors 500.

The package substrate 110 may include an insulating layer 111, an interconnection layer 112, and lower connection pads 112L. The package substrate 110 may further include a via structure electrically connecting interconnection layers 112, which are positioned on different levels, to each other. The package substrate 110 may be a semiconductor package substrate including, for example, a printed circuit board (PCB), a ceramic substrate, a glass substrate, or a tape interconnection substrate.

The package substrate 110 may have a first region R1 and a second region R2 adjacent to the first region R1. The first region R1 may include a central portion of the package substrate 110, and the second region R2 may include an external surface of the package substrate 110, and may surround the first region R1. The first region R1 may be a region electrically connecting the semiconductor chip 200, which is mounted on the package substrate 110, to the package substrate 110, and the second region R2 may be positioned around the first region R1. The semiconductor chip 200 may be supported by the second region R2 and may be stably mounted on the package substrate 110. The connection pads 121 and 122 for mounting the semiconductor chip 200 on the package substrate 110 may be referred to as the first connection pads 121 or the second connection pads 122 depending on the regions R1 and R2 of the package substrate 110 in which the connection pads 121 and 122 are disposed. For example, the first connection pads 121 are disposed in the first region R1, and the second connection pads 122 are disposed in the second region R2.

The insulating layer 111 may include an insulating resin. The insulating resin may include a thermosetting resin such as an epoxy resin, a thermoplastic resin such as polyimide, or a resin in which the thermosetting resin or the thermoplastic resin is impregnated with an inorganic filler and/or a glass fiber (or glass cloth or glass fabric), for example, a prepreg, an Ajinomoto build-up film (ABF), FR-4, bismaleimide triazine (BT). The insulating resin may include a photosensitive resin such as a photoimageable dielectric (PID). For example, when the package substrate 110 is a

PCB substrate, the insulating layer 111 may be a core insulating layer (for example, a prepreg) of a copper clad laminate. The insulating layer 111 may have a form in which a large number of insulating layers are stacked in a vertical direction (Z-direction), and the insulating layers that are stacked on each other at different levels may have unclear boundaries therebetween depending on the formation process.

The interconnection layer 112 may be disposed within the insulating layer 111, and may form an electrical path within the package substrate 110. The interconnection layer 112 may include at least one of a metal or an alloy of two or more metals, among, for example, copper (Cu), aluminum (Al), nickel (Ni), silver (Ag), gold (Au), platinum (Pt), tin (Sn), lead (Pb), titanium (Ti), chromium (Cr), palladium (Pd), indium (In), zinc (Zn), and/or carbon (C). The interconnection layer 112 may be a plurality of interconnection layers 112, which are positioned on different levels, between a plurality of insulating layers 111.

A plurality of lower connection pads 112L may be electrically connected to a plurality of external connection conductors 500, which are disposed below the insulating layer 111.

A protective layer 113 may be disposed on an upper surface of the package substrate 110. The protective layer 113 may serve to protect the interconnection layer 112 from external physical/chemical damage, and may be disposed on an uppermost and/or lowermost insulating layer 111 among the plurality of insulating layers 111. The protective layer 113 may be a solder resist layer. The solder resist layer may include an insulating material, and may be formed using, for example, a prepreg, an ABF, FR-4, BT, or a photo solder resist (PSR).

The first connection pads 121 may be disposed on the first region R1 of the package substrate 110. The first connection pads 121 may have a tapered shape from the upper surface of the package substrate 110 toward a lower surface of the semiconductor chip 200. For example, a width of each of the first connection pads 121 may decrease from the package substrate 110 to the semiconductor chip 200. The first connection pads 121 may have a trapezoidal shape having an upper end having a horizontal width that is narrower than a horizontal width of a lower end thereof, but the present inventive concept is not limited thereto. A height of the first connection pads 121, that is, a vertical distance from the upper surface of the package substrate 110 to upper surfaces 121U of the first connection pads 121, may be referred to as a first height H1. The first height H1 of the first connection pads 121 may range, for example, from about 10 μm to about 16 μm, from about 11 μm to about 15 μm, or from about 13 μm to about 15 μm, but the present inventive concept is limited thereto.

The first connection pads 121 may include at least one of, for example, aluminum (Al), copper (Cu), nickel (Ni), tungsten (W), platinum (Pt), and/or gold (Au). For example, the first connection pads 121 may include copper (Cu). The first connection pads 121 may have a conductive layer structure that is formed by using a plating process, and may include a seed layer formed on the upper surface of the package substrate 110.

The second connection pads 122 may be disposed on the second region R2 of the package substrate 110, and may be disposed to be spaced apart from the first connection pads 121. The second connection pads 122 may have features the same as or similar to those of the first connection pads 121, and thus, a repeated description of the second connection pads 122 may be replaced with the above-described description of the first connection pads 121. A height of the second connection pads 122, that is, a vertical distance from the upper surface of the package substrate 110 to upper surfaces 122U of the second connection pads 122, may be referred to as a second height H2. The second height H2 of the second connection pads 122 may range, for example, from about 5 μm to about 10 μm, from about 6 μm to about 9 μm, or from about 6 μm to about 7 μm, but the present inventive concept is not limited thereto. The first height H1 may be about twice the second height H2, but the present inventive concept is not limited thereto. The upper surfaces 121U of the first connection pads 121 may be positioned on a level that is higher than that of the upper surfaces 122U of the second connection pads 122.

The semiconductor chip 200 may be disposed on the upper surface of the package substrate 110, and may include chip pads 210 and 220 electrically connected to the interconnection layers 112. The semiconductor chip 200 may be an integrated circuit (IC) that is in a bare state in which a bump or interconnection layer is not formed, but the present inventive concept is not limited thereto, and may be a packaged type integrated circuit. The integrated circuit may be a processor chip such as a central processor (CPU), a graphics processing unit (GPU), a field programmable gate array (FPGA), an application processor (AP), a digital signal processor, a cryptographic processor, a microprocessor, or a microcontroller, but the present inventive concept is not limited thereto, and may be a logic chip such as an analog-digital converter or an application-specific IC (ASIC), or a memory chip including a volatile memory such as a dynamic RAM (DRAM) or a static RAM (SRAM), and a non-volatile memory such as a phase change RAM (PRAM), a magnetic RAM (MRAM), a resistive RAM (RRAM), or a flash memory.

The semiconductor chip 200 may include chip pads 210 and 220 and a protective insulating layer 230. The chip pads 210 and 220 may be respectively disposed on the first and second regions R1 and R2 of the package substrate 110, and may be referred to as first chip pads 210 and second chip pads 220. The first chip pads 210 may be disposed in the first region R1 of the package substrate 110, and may be disposed on the semiconductor chip 200. The first chip pads 210 may overlap the first connection pads 121 in the vertical direction (for example, Z-axis direction), and may be connected to each other by first bump structures 310. The first chip pads 210 may be active pads, serving to transmit electrical signals between the semiconductor chip 200 and the package substrate 110.

The second chip pads 220 may be disposed in the second region R2 of the package substrate 110, and may be disposed on the semiconductor chip 200. The second chip pads 220 may overlap the second connection pads 122 in the vertical direction (for example, Z-axis direction), and may be in contact with the protective insulating layer 230. The second chip pads 220 may be in contact with an insulating material, and may be inactive pads or dummy pads that do not transmit electrical signals. For example, the second chip pads 220 might not be electrically connected to the second connection pads 122.

The protective insulating layer 230 may be disposed on second bump structures 320, on the second region R2 of the package substrate 110. The protective insulating layer 230 is illustrated as being connected to a plurality of second bump structures 320, but the present inventive concept is not limited thereto, and may connected to each of the second bump structures 320. The protective insulating layer 230 may include an insulating material, for example, an organic compound such as photosensitive polyimide (PSPI). The protective insulating layer 230 may have a third height H3. In the semiconductor package, according to an example embodiment of the present inventive concept, the second height H2 of the second connection pads 122, overlapping the protective insulating layer 230 in the vertical direction, may be smaller than the third height H3. Since the second connection pads 122 has the lower second height H2, a non-wetting phenomenon, which may occur between connection pads and bump structures due to a step occurring when the protective insulating layer 230 that serves as a support is disposed on a lower portion of the semiconductor chip 200, may be resolved. Accordingly, the second height H2 of the second connection pads 122 may be substantially equal to a difference between the first height H1 of the first connection pads 121 and the third height H3 of the protective insulating layer 230.

The bump structures 300 may be disposed on the first connection pads 121 and the second connection pads 122. The bump structures 300 may include first bump structures 310, which are respectively connected to the first connection pads 121, and second bump structures 320, which respectively connected to the second connection pads 122. The first bump structures 310 may electrically connect the first chip pads 210 to the interconnection layer 112 through the first connection pads 121. Each of the first bump structures 310 may include a first pillar portion 310P, which is in contact with the first chip pads 210, and a first solder portion 310S, which connects the first pillar portion 310P to the first connection pads 121 and the interconnection layer 112. For example, the first pillar portion 310P may be a metal post portion, and the first solder portion 310S may be a solder portion including a low melting point metal, but the present inventive concept is not limited thereto. In some example embodiments of the present inventive concept, the first bump structures 310 may include only the first solder portion 310S. The low melting point metal may include, for example, tin (Sn), indium (In), bismuth (Bi), antimony (Sb), copper (Cu), silver (Ag), zinc (Zn), lead (Pb), or alloys thereof (for example, Sn—Ag—Cu).

The second bump structures 320 may have features the same as or similar to those of the first bump structures 310, and thus a repeated description of the second bump structures 320 may be replaced with the above-description of the first bump structures 310. For example, differences between the second bump structure 320 and the first bump structures 310 may be discussed hereinafter. Each of the second bump structures 320 may include a second pillar portion 320P, which is in contact with the protective insulating layer 230, and a second solder portion 320S, which connects the second pillar portion 320P and the second connection pads 122 to each other. The second pillar portion 320P may have a height the same as that of the first pillar portion 310P, but the second solder portion 320S may have a height different from that of the first solder portion 310S. As the second connection pads 122 have a lowered height, the second solder portion 320S, surrounding the second connection pads 122, may also have a lowered height. For example, an upper surface of the second solder resist 320S may be lower than an upper surface of the first solder resist 310S. The first bump structures 310 may have a height greater than a height of the second bump structures 320. Upper surfaces of the first bump structures 310 may be positioned on a level higher than that of upper surfaces of the second bump structures 320. The upper surfaces of the first bump structures 310 may be substantially coplanar with a lower surface of the semiconductor chip 200, and thus, may be substantially coplanar with an upper surface of the protective insulating layer 230 The upper surfaces of the first bump structures 310 may be positioned on a level the same as that of the upper surface of the protective insulating layer 230. The encapsulant 400 may seal at least a portion of each of the semiconductor chip 200, the first connection pads 121, the second connection pads 122, and the bump structures 300, on the upper surface of the package substrate 110. The encapsulant 400 may include, for example, a thermosetting resin such as an epoxy resin, a thermoplastic resin such as polyimide, or a prepreg, an ABF, FR-4, BT, an epoxy molding compound (EMC) in which the thermosetting resin or the thermoplastic resin is impregnated with an inorganic filler. The encapsulant 400 may be disposed on with the semiconductor chip 200, the first connection pads 121, the second connection pads 122, and the bump structures 300, on the package substrate 110. For example, the encapsulant 400 may be in contact with the semiconductor chip 200, the first connection pads 121, the second connection pads 122, and the bump structures 300.

The external connection conductors 500 may be disposed below the package substrate 110, and may be electrically connected to the interconnection layer 112. The external connection conductors 500 may physically and/or electrically connect the semiconductor package 100A to an external device. The external connection conductors 500 may include a conductive material, and may be in the form of a ball, pin, or lead. For example, the external connection conductors 500 may be solder balls.

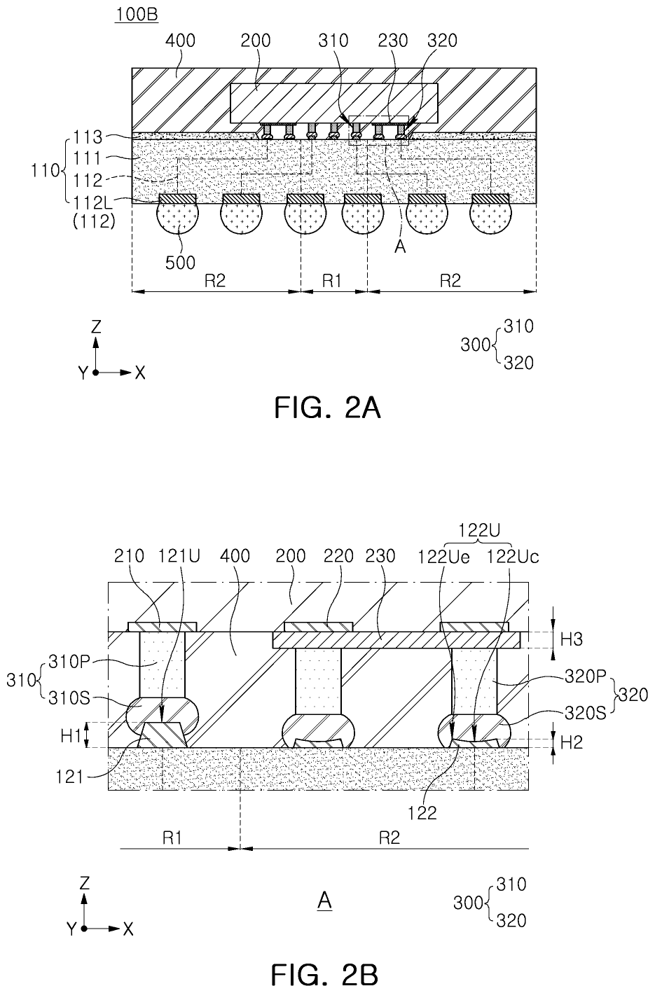

FIG. 2A is a cross-sectional view illustrating a semiconductor package 100B according to an example embodiment of the present inventive concept, and FIG. 2B is a partially enlarged view illustrating region “A” of FIG. 2A.

Referring to FIGS. 2A and 2B, the semiconductor package 100B according to an example embodiment of the present inventive concept may have features the same as or similar to those described with reference to FIGS. 1A and 1B, except that upper surfaces 122U of second connection pads 122 have a concave shape toward a lower surface of a semiconductor chip 200. The upper surfaces 122U of the second connection pads 122 in the semiconductor package 100B according to the present example embodiment may have a more recessed central portion than an outside thereof, and the central portion 122Uc may be positioned on a level lower than that that of the outside portion 122Ue. The second connection pads 122 may be in contact with a second solder portion 320S, among second bump structures 320. The upper surfaces 122U of the second connection pads 122 may have a concave structure, such that a surface area of the second connection pads 122, which is in contact with the second solder portion 320S, may increase. As a result, the second solder portion 320S may be more stably attached to the second connection pads 122 and a package substrate 110, thereby improving a non-wetting phenomenon.

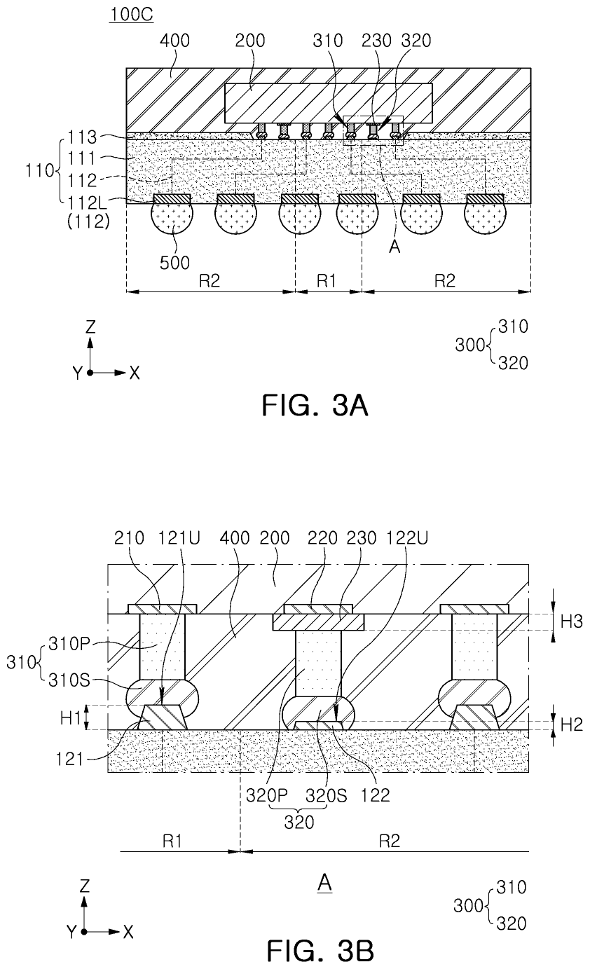

FIG. 3A is a cross-sectional view illustrating a semiconductor package 100C according to an example embodiment of the present inventive concept, and FIG. 3B is a partially enlarged view illustrating region “A” of FIG. 3A.

Referring to FIGS. 3A and 3B, the semiconductor package 100C according to an example embodiment of the present inventive concept may have features the same as or similar to those described with reference to FIGS. 1A to 2B, except that first connection pads 121, adjacent to a side surface of a package substrate 110 in a horizontal direction, are further included. The first connection pads 121 having a first height H1 and second connection pads 122 having a second height H2 may be disposed to be spaced apart from each other. The first connection pads 121 may be disposed on a first region R1 of the package substrate 110, and the second connection pads 122 may be disposed on a second region R2 of the package substrate 110. However, the present inventive concept is not necessarily limited to a structure in which the first region R1 is surrounded by the second region R2. In a semiconductor chip 200, a region in which a protective insulating layer 230 is disposed is not limited to one region, and the second connection pads 122 may be disposed on a region overlapping the protective insulating layer 230 in a vertical direction (for example, Z-axis direction), thereby increasing a degree of freedom in the arrangement of a semiconductor package.

In an example embodiment of the present inventive concept, the first connection pads 121 may be disposed in the second region R2. For example, the first connection pads 121 that are in the second region R2 may be disposed closer to the side surfaces of the package 110 than second connection pads 122.

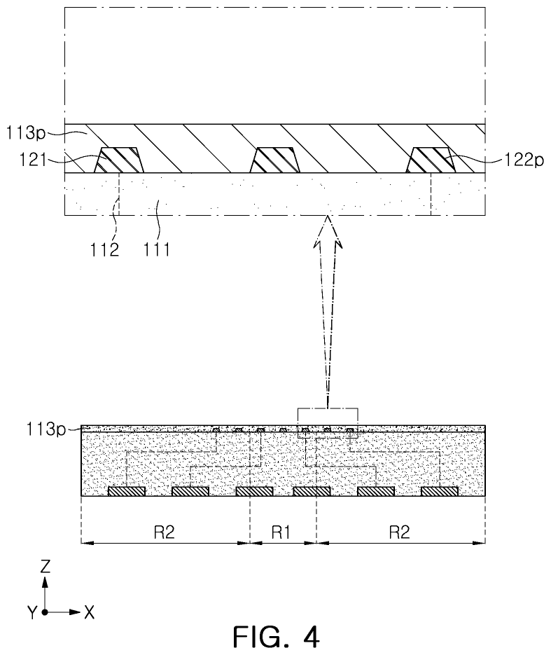

FIGS. 4 to 7 are schematic cross-sectional views illustrating a process of manufacturing a semiconductor package according to an example embodiment of the present inventive concept.

Referring to FIG. 4, preliminary connection pads 121 and 122p may be formed on a preliminary package substrate, and a preliminary protective layer 113p may be formed to cover the preliminary connection pads 121 and 122p.

The preliminary protective layer 113p may be a solder resist layer. The solder resist layer may include an insulating material, and may be formed using, for example, a prepreg, an ABF, FR-4, BT, or a photo solder resist (PSR). To protect first and second connection pads 121 and 122 and/or an interconnection layer 112, which is disposed below the preliminary protection layer 113p, the preliminary protective layer 113p may be disposed on an uppermost side of the insulating layer 111 and may extend in a horizontal direction.

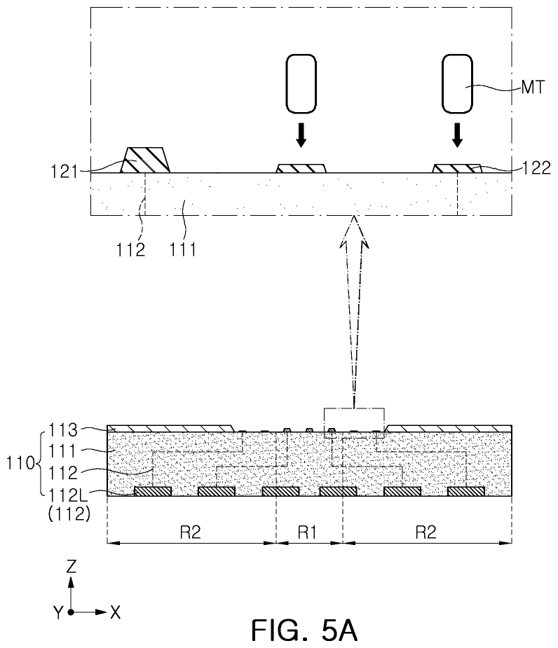

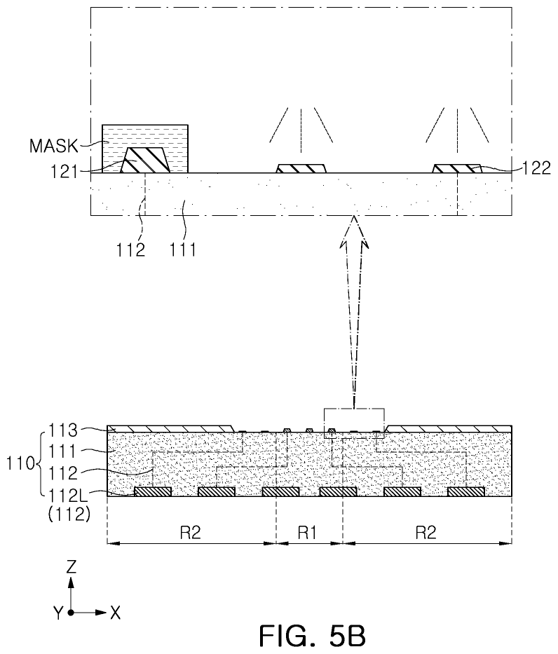

Referring to FIGS. 5A and 5B, a portion of the preliminary protection layer 113p may be removed to expose the first connection pads 121 and the second preliminary connection pads 122p, and at least a portion of the preliminary second connection pads 122p may be removed to form the second connection pads 122. The remainder of the preliminary protection layer 113p may form the protective layer 113, and the package substrate 110 may be formed from the preliminary package substrate. FIG. 5A is a schematic diagram illustrating a mechanical polishing process for forming the second connection pads 122, and FIG. 5B is a schematic diagram illustrating a chemical etching process for forming the second connection pads 122. The two processes may be selectively performed to form the second connection pads 122.

Referring to FIG. 5A, a portion of the preliminary second connection pads 122p may be removed by using a metal tip MT to form the second connection pads 122.

The metal tip MT may be repeatedly hit in a direction of an arrow (e.g., a downward direction), thereby polishing or compressing a portion of upper ends of the preliminary second connection pads 122p. A movement radius of the metal tip MT may be adjusted, and accordingly, a portion in which the preliminary second connection pads 122p are removed may be adjusted, and further, a second height H2 of the formed second connection pads 122 may be adjusted. The second height H2 of the second connection pads 122 may be about half of a first height H1 of the first connection pads 121, but the present inventive concept is not limited thereto.

Referring to FIG. 5B, at least a portion of upper ends of the preliminary second connection pads 122p may be etched to form the second connection pads 122.

An etchant may be sprayed on the preliminary second connection pads 122p that are to be etched to adjust a portion being etched and an amount of the preliminary second connection pads 122p being etched, and upper ends of the first connection pads 121 may be covered with a photoresist mast MASK. An amount of etchant being sprayed, for example, a spraying speed, may be adjusted to adjust an amount of the preliminary second connection pads 122p being etched. In addition, the second height H2 of the formed second connection pads 122 may be adjusted.

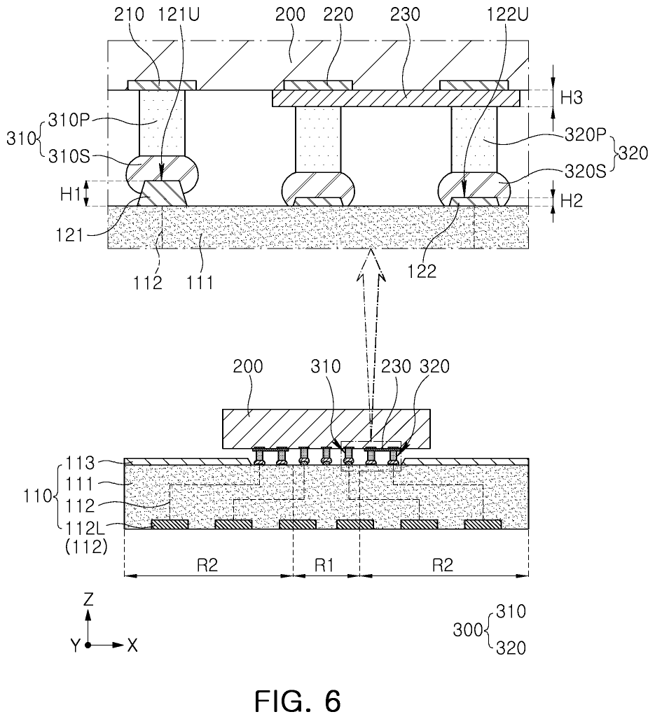

Referring to FIG. 6, a semiconductor chip 200 may be mounted on connection pads 121 and 122 through bump structures 300.

First bump structures 310 may be in contact with first chip pads 210 of the semiconductor chip 200, and second bump structures 320 may be in contact with a protective insulating layer 230 of the semiconductor chip 200. The first bump structures 310 may overlap the first connection pads 121 in a vertical direction (for example, Z-axis direction), and the second bump structures 320 may overlap the second connection pads 122 in the vertical direction. Solder portions 310S and 320S of the bump structures 300 may be formed to cover both the first and second connection pads 121 and 122 in some example embodiments of the present inventive concept.

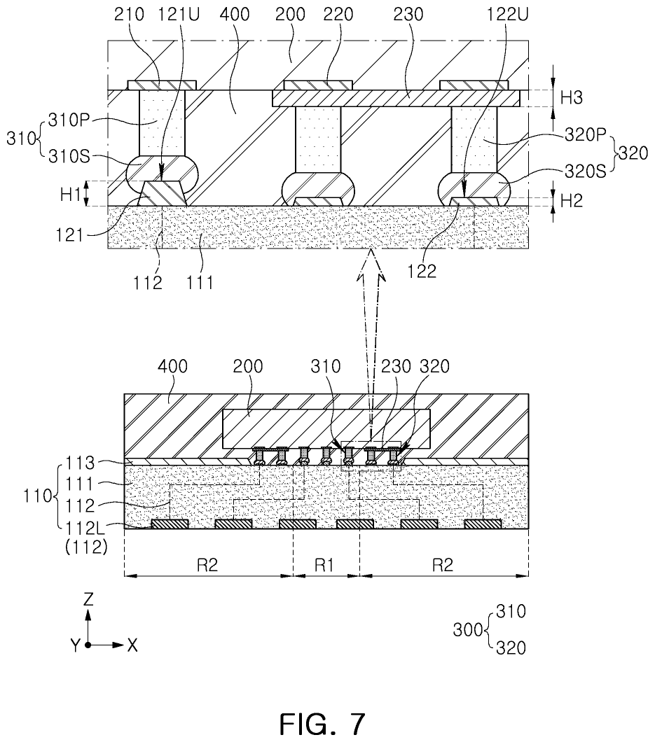

Referring to FIG. 7, a package substrate 110 may be filled with an encapsulating material, and then the encapsulating material 400 may be formed by using a curing process.

The encapsulating material may be filled between a lower surface of the semiconductor chip 200 and an upper surface of the package substrate 110. The encapsulant 400 may have a molded under-fill (MUF) form in which no underfill is present between the semiconductor chip 200 and the package substrate 110. The encapsulant 400 may be disposed on the package substrate 110, and may cover at least a portion of each of the semiconductor chip 200 and the bump structures 300. The encapsulant 400 may cover at least a portion of each of the first connection pads 121 and the second connection pads 122. However, in some example embodiments of the present inventive concept, when a solder portion of the bump structures 300 surrounds the connection pads 121 and 122 and there is no externally exposed portion, the encapsulant 400 might not be in contact with the connection pads 121 and 122.

Referring to FIGS. 1A and 1B, the external connection conductors 500 may be attached to a lower portion of the package substrate 110, and the semiconductor package 100A according to an example embodiment of the present inventive concept may be formed. The external connection conductors 500 may be attached to the lower connection pads 112L.

According to example embodiments of the present inventive concept, pads having a low height, which compensates for a height difference occurring based on the presence or absence of a protective insulating layer, may be introduced, thereby providing a semiconductor package having increased reliability.

While the present inventive concept has been described with reference to embodiments thereof, it will be understood by those of ordinary skill in the art that various changes in form and details may be made thereto without departing from the spirit and scope of the present inventive concept.

1. A semiconductor package comprising:
a package substrate having a first region and a second region that is adjacent to the first region;
first connection pads disposed on the first region of the package substrate, wherein each of the first connection pads has a first height;
second connection pads disposed on the second region of the package substrate, wherein each of the second connection pads has a second height that is lower than the first height;
a semiconductor chip including first chip pads, second chip pads, and a protective insulating layer, wherein the first chip pads are disposed in the first region, wherein the second chip pads are disposed in the second region, and wherein the protective insulating layer is disposed on the second chip pads;
first bump structures disposed on the first chip pads, wherein the first bump structures are respectively connected to the first connection pads; and
second bump structures disposed on the protective insulating layer, wherein the second bump structures are respectively connected to the second connection pads.

2. The semiconductor package of claim 1, wherein upper surfaces of the second connection pads have a concave shape protruding toward the package substrate.

3. The semiconductor package of claim 1, wherein
the first region includes a central portion of the package substrate, and
the second region includes an external surface of the package substrate, and surrounds the first region.

4. The semiconductor package of claim 1, wherein the first bump structures have a height that is greater than a height of the second bump structures.

5. The semiconductor package of claim 1, wherein the first bump structures electrically connect the semiconductor chip and the package substrate to each other.

6. The semiconductor package of claim 1, wherein
each of the first and second bump structures has a solder portion and a pillar portion, wherein the solder portion is in contact with at least one of the first or second connection pads, and wherein the pillar portion is disposed on the solder portion, and
the pillar portions of the first and second bump structures have the same height as each other.

7. The semiconductor package of claim 1, wherein
the protective insulating layer has a third height, and
the second height is substantially equal to a difference between the first height and the third height.

8. The semiconductor package of claim 1, further comprising:
external connection conductors disposed on a lower surface of the package substrate.

9. The semiconductor package of claim 1, wherein the first height is about twice the second height.

10. The semiconductor package of claim 9, wherein
the first height is about 14 μm, and
the second height is about 7 μm.

11. The semiconductor package of claim 1, wherein each of the first and second connection pads include copper (Cu).

12. The semiconductor package of claim 1, wherein the first and second connection pads have a tapered shape.

13. A semiconductor package comprising:
a package substrate;
first and second connection pads disposed on the package substrate and spaced apart from each other;
bump structures in contact with at least one of the first or second connection pads; and
a semiconductor chip disposed on the bump structures, wherein the semiconductor chip includes a protective insulating layer disposed on bump structures, which overlap the second connection pads, among the bump structures,
wherein upper surfaces of the first connection pads are positioned on a level higher than that of upper surfaces of the second connection pads.

14. The semiconductor package of claim 13, wherein upper surfaces of the bump structures, which contact the first connection pads, are positioned on a level higher than that of upper surfaces of the bump structures, which contact the second connection pads.

15. The semiconductor package of claim 13, wherein upper surfaces of the bump structures, which contact the first connection pads, are positioned on a level the same as that of an upper surface of the protective insulating layer.

16. The semiconductor package of claim 13, wherein the upper surfaces of the second connection pads have a central portion and a peripheral portion, wherein the central portion is positioned on a level lower than a level of the peripheral portion.

17. The semiconductor package of claim 13, wherein
outermost first connection pads of the first connection pads are more adjacent to side surfaces of the package substrate than the second connection pads, on the package substrate.

18-20. (canceled)
